(19) United States
(12) Patent Application Publication
(10) Pub. No.: US 2024/0274417 A1
(43) Pub. Date: Aug. 15, 2024

(54) PLASMA MEASUREMENT METHOD AND PLASMA PROCESSING APPARATUS

(71) Applicant: TOKYO ELECTRON LIMITED, Tokyo (JP)

(72) Inventor: Mitsutoshi ASHIDA, Yamanashi (JP)

(21) Appl. No.: 18/429,046

(22) Filed: Jan. 31, 2024

(30) Foreign Application Priority Data
Feb. 13, 2023 (JP) 2023-020210

(51) Int. Cl. H01J 37/32; G01R 19/00

(52) U.S. Cl. CPC H01J 37/32935; G01R 19/0061

(57) ABSTRACT

Provided is a plasma measurement method for measuring a plasma state using a probe device that is provided in a plasma processing apparatus, and a measurement circuit including a signal transmitter that outputs an AC voltage, the method comprising: measuring a first current including a magnitude and phase of current in the measurement circuit when the AC voltage is output from the signal transmitter to the probe device, in a state where no plasma is generated in the plasma processing apparatus; measuring a second current including a magnitude and phase of current in the measurement circuit when the AC voltage is output from the signal transmitter to the probe device, in a state where plasma is generated in the plasma processing apparatus; and measuring current flowing through the plasma by vector operation using the magnitude and phase of the current included in the measured first current and second current.

### CROSS-REFERENCE TO RELATED APPLICATIONS

This application claims priority to Japanese Patent Application No. 2023-020210, filed on Feb. 13, 2023, the entire contents of which are incorporated herein by reference.

### TECHNICAL FIELD

The present disclosure relates to a plasma measurement method and a plasma processing apparatus.

### BACKGROUND

For example, Japanese Laid-open Patent Publication No. 2019-46787 discloses a probe device having an antenna part that is installed in an opening formed in a wall of a processing container, an electrode that is connected to the antenna part, and a dielectric support that is formed of a dielectric material and supports the antenna part from a periphery.

### SUMMARY

The present disclosure provides a technology that can more precisely measure a plasma state.

In accordance with an aspect of the present disclosure, there is provided a plasma measurement method for measuring a plasma state using a probe device that is provided in a plasma processing apparatus, and a measurement circuit including a signal transmitter that outputs an AC voltage, the method comprising: step (A) of measuring a first current including a magnitude and phase of current in the measurement circuit when the AC voltage is output from the signal transmitter to the probe device, in a state where no plasma is generated in the plasma processing apparatus; step (B) of measuring a second current including a magnitude and phase of current in the measurement circuit when the AC voltage is output from the signal transmitter to the probe device, in a state where plasma is generated in the plasma processing apparatus; and step (C) of measuring current flowing through the plasma by vector operation using the magnitude and phase of the current included in the measured first current and second current.

### BRIEF DESCRIPTION OF THE DRAWINGS

FIG. 1 is a schematic sectional view showing an example of a plasma processing apparatus according to an embodiment.

FIG. 2 is a diagram showing an example of a section taken along line II-II of FIG. 1.

FIG. 3 is a diagram showing an example of a functional configuration of a measurement system and a control device according to an embodiment.

FIGS. 4A and 4B are diagrams showing an example of a measured current signal and a frequency analysis result of the signal, respectively.

FIGS. 5A and 5B are diagrams showing an example of an equivalent circuit of a measurement system according to an embodiment.

FIGS. 6A, 6B, and 6C are diagrams for explaining a plasma measurement method according to an embodiment.

FIG. 7 is a flowchart illustrating an example of the plasma measurement method (preparation) according to an embodiment.

FIG. 8 is a flowchart illustrating an example of the plasma measurement method (preparation) according to an embodiment.

### DETAILED DESCRIPTION

Hereinafter, an embodiment of the present disclosure will be described with reference to the accompanying drawings. The same reference numerals are used throughout the drawings to designate the same or similar components, and redundant descriptions thereof will be omitted.

### <Plasma Processing Apparatus>

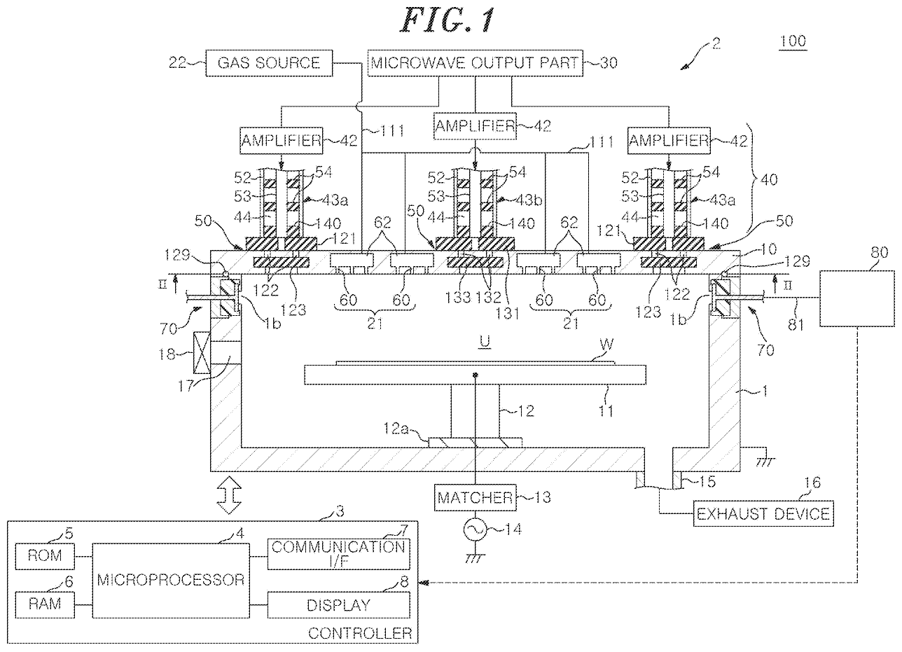

FIG. 1 shows an example of a sectional view of a plasma processing apparatus 100 according to an embodiment of the present disclosure. The plasma processing apparatus 100 has a processing container 1 that accommodates a substrate W, an example of which is a semiconductor wafer. The plasma processing apparatus 100 is an example of the plasma processing apparatus that performs plasma processing on the substrate W using surface wave plasma formed on the lower surface of the upper wall 10 of the processing container 1 by microwaves. Examples of plasma processing include film formation processing, etching processing, or ashing processing using plasma.

The plasma processing apparatus 100 includes a processing container 1, a microwave plasma source 2, and a control device 3. The processing container 1 is a substantially cylindrical container that is airtight, is made of a metal material such as aluminum or stainless steel, and is grounded.

The processing container 1 has the upper wall 10, and defines a space (plasma generating space U) in which the substrate W is subjected to plasma processing. The upper wall 10 has a disc shape, and is a lid that closes an upper opening of the processing container 1. A support ring 129 is provided on a contact surface between the processing container 1 and the upper wall 10, thereby allowing the inside of the processing container 1 to be hermetically sealed. The upper wall 10 is made of a metal material such as aluminum or stainless steel.

The microwave plasma source 2 includes a microwave output part 30, a microwave transmission part 40, and a microwave radiation mechanism 50. The microwave output part 30 outputs the microwaves by distributing them to a plurality of paths. The microwaves are introduced into the processing container 1 through the microwave transmission part 40 and the microwave radiation mechanism 50. Gas supplied into the processing container 1 is excited by the electric field of the introduced microwaves, thereby forming surface wave plasma.

A mounting table 11 on which the substrate W is mounted is provided in the processing container 1. The mounting table 11 is supported by a cylindrical support member 12 that is erected at the center of the bottom of the processing container 1 with an insulating member 12a interposed therebetween. Examples of materials forming the mounting table 11 and the support member 12 include metal such as aluminum whose surface is subjected to alumite treatment (anodizing treatment) or an insulating member (ceramics, etc.) having a high-frequency electrode therein. The mounting table 11 may be provided with an electrostatic chuck for electrostatically adsorbing the substrate W, a temperature control mechanism, a gas flow path for supplying heat transfer gas to the back surface of the substrate W, and the like.

A high-frequency bias power source 14 is connected to the mounting table 11 via a matcher 13. By supplying high-frequency power from the high-frequency bias power source 14 to the mounting table 11, ions in the plasma are drawn toward the substrate W. Further, the high-frequency bias power source 14 may not be provided depending on the characteristics of plasma processing.

An exhaust pipe 15 is connected to the bottom of the processing container 1, and an exhaust device 16 including a vacuum pump is connected to the exhaust pipe 15. When the exhaust device 16 is activated, the interior of the processing container 1 is evacuated, thereby rapidly reducing pressure in the processing container 1 to a predetermined vacuum level. A sidewall of the processing container 1 is provided with a loading/unloading port 17 for loading and unloading the substrate W, and a gate valve 18 for opening and closing the loading/unloading port 17.

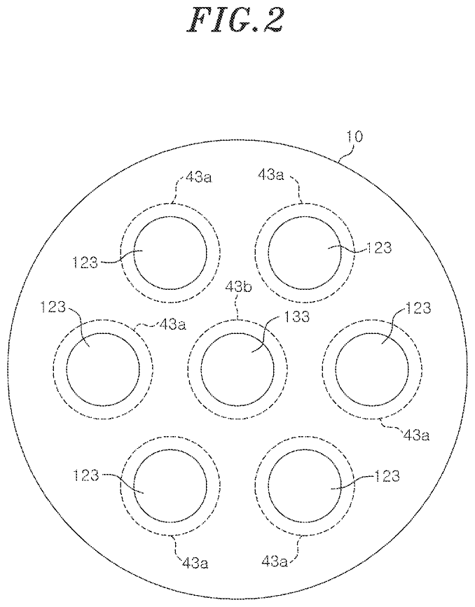

The microwave transmission part 40 transmits microwaves that are output from the microwave output part 30. FIG. 2 is a sectional view taken along line II-II of FIG. 1, and shows an example of the lower surface of the upper wall of the plasma processing apparatus 100. Referring to FIG. 2, a central microwave introduction part 43b in the microwave transmission part 40 is arranged at the center of the upper wall 10, and six peripheral microwave introduction parts 43a are arranged at equal intervals in a circumferential direction around the upper wall 10. The central microwave introduction part 43b and the six peripheral microwave introduction parts 43a have the function of introducing the microwaves, output from correspondingly provided amplifier 42 shown in FIG. 1, into the microwave radiation mechanism 50 and the function of matching impedance. Hereinafter, the peripheral microwave introduction parts 43a and the central microwave introduction part 43b are collectively referred to as the microwave introduction part 43.

As shown in FIGS. 1 and 2, six dielectric windows 123 on an outer peripheral side are arranged inside the upper wall 10 under the six peripheral microwave introduction parts 43a. Further, one dielectric window 133 at the center is arranged inside the upper wall 10 under the central microwave introduction part 43b. The numbers of the peripheral microwave introduction parts 43a and dielectric windows 123 are not limited to six, but may be two or more. However, the number of peripheral microwave introduction parts 43a is preferably three or more, and may be, for example, three to six.

The microwave radiation mechanism 50 shown in FIG. 1 has slow wave plates 121 and 131, slots 122 and 132, and dielectric windows 123 and 133. The slow wave plates 121 and 131 are formed of a disc-shaped dielectric material that transmits the microwave, and are arranged on the upper surface of the upper wall 10. The slow wave plates 121 and 131 are formed of ceramics such as quartz and alumina (Al₂O₃), fluorine-based resins such as polytetrafluoroethylene, and polyimide-based resins, which have a relative dielectric constant greater than that of vacuum. This has the function of making the wavelength of the microwave transmitted through the slow wave plates 121 and 131 shorter than the wavelength of the microwave propagating in vacuum, thereby making an antenna including the slots 122 and 132 smaller.

Under the slow wave plates 121 and 131, the dielectric windows 123 and 133 contact the back surface of the opening of the upper wall 10 via the slots 122 and 132 formed in the upper wall 10. The dielectric windows 123 and 133 are formed of ceramics such as quartz and alumina (Al₂O₃), fluorine-based resins such as polytetrafluoroethylene, and polyimide-based resins. The dielectric windows 123 and 133 are provided at positions recessed from a ceiling surface by the thickness of the opening formed in the upper wall 10, and supply the microwave to a plasma generation space U.

In the peripheral microwave introduction part 43a and the central microwave introduction part 43b, a cylindrical outer conductor 52 and a rod-shaped inner conductor 53 provided at the center thereof are coaxially arranged. Microwave power is supplied between the outer conductor 52 and the inner conductor 53, forming a microwave transmission path 44 through which the microwave propagates toward the microwave radiation mechanism 50.

The peripheral microwave introduction part 43a and the central microwave introduction part 43b are provided with a slag 54 and an impedance adjustment member 140 located at a tip thereof. This has the function of matching the impedance of load (plasma) in the processing container 1 with the characteristic impedance of the microwave power source in the microwave output part 30, by moving the slag 54. The impedance adjustment member 140 is formed of a dielectric material, and is adapted to adjust the impedance of the microwave transmission path 44 based on its relative dielectric constant.

The upper wall 10 is provided with a gas introduction part 21 having a shower structure. Gas supplied from the gas source 22 passes from a gas diffusion chamber 62 through the gas introduction part 21 via a gas supply pipe 111, and is supplied into the processing container 1 in the form of a shower. The gas introduction part 21 is an example of a gas shower head that supplies gas from a plurality of gas supply holes 60 formed in the upper wall 10. Examples of the gas include plasma generating gas such as Ar gas, gas to be decomposed with high energy such as O₂ gas or N₂ gas, and processing gas such as silane gas.

Each part of the plasma processing apparatus 100 is controlled by a control device 3. The control device 3 has a microprocessor 4, a Read Only Memory (ROM) 5, and a Random Access Memory (RAM) 6. The ROM 5 or the RAM 6 stores a process sequence and a process recipe, which is a control parameter, of the plasma processing apparatus 100. The microprocessor 4 controls each part of the plasma processing apparatus 100, on the basis of the process sequence and the process recipe. Further, the control device 3 has a communication interface (I/F) 7, and may communicate with other devices. Further, the control device 3 has a display 8, and may display results when performing a predetermined control according to the process sequence and the process recipe.

When performing plasma processing in the plasma processing apparatus 100 having such a configuration, the substrate W is first transported from the open gate valve 18 through the loading/unloading port 17 into the processing container 1 while being held on a transfer arm (not shown). When the substrate W is transported above the mounting table 11, it is transferred from the transfer arm to a pusher pin and is mounted on the mounting table 11 by lowering the pusher pin. The gate valve 18 is closed after loading the substrate W. Pressure in the processing container 1 is maintained at a predetermined vacuum level by the exhaust device 16. Processing gas is introduced in the form of a shower from the gas introduction part 21 into the processing container 1. The microwave emitted from the microwave radiation mechanism 50 through the microwave introduction part 43 propagates near the lower surface, which is the inner surface of the upper wall. The gas is excited by the electric field of the surface wave microwave, and the substrate W is subjected to plasma processing by the surface wave plasma generated in the plasma generating space U under the upper wall in the processing container 1.

### [Probe Device]

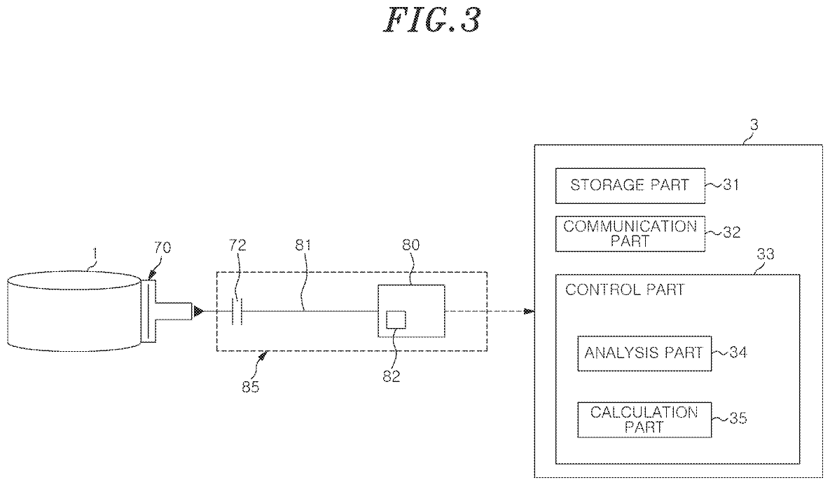

The description of the probe device 70 will be continued with reference to FIGS. 1 and 3. FIG. 3 is a diagram showing an example of the functional configuration of a measurement system and a control device according to an embodiment. As shown in FIG. 1, one or more openings 1b are formed in a sidewall of the processing container 1 in a circumferential direction thereof, and one or more probe devices 70 are installed via a sealing member (not shown) that seals between the vacuum space and the atmospheric space.

A gap with a predetermined width is formed between an end surface of the probe device 70 and a back surface near the opening 1b of the wall of the processing container 1. The gap is designed to be wide enough that the probe device 70 is not connected to the wall of the processing container 1 in a DC manner, but narrow enough to prevent plasma or gas from entering. However, the probe device 70 may be attached to the opening formed in the mounting table via the sealing member.

As shown in FIG. 3, the measurement system for measuring the plasma state includes the probe device 70 and the measurement circuit 85. The measurement circuit 85 includes a monitor device 80, a capacitor 72, and a coaxial cable 81. The monitor device 80 is connected to the control device 3 to communicate therewith.

The probe device 70 is connected to the monitor device 80 via the coaxial cable 81 outside the plasma processing apparatus 100. The monitor device 80 has a signal transmitter 82, and the signal transmitter 82 outputs an AC voltage signal of a predetermined frequency to the coaxial cable 81. The AC voltage signal is transmitted through the coaxial cable 81, and the AC voltage is applied to the probe device 70. The capacitor 72 is connected to the coaxial cable 81, transmits the AC voltage signal to the probe device 70, and blocks a DC voltage signal. Thereby, the monitor device 80 receives only the AC voltage signal from a plasma side.

The probe device 70 senses plasma generated in the plasma generating space U. The probe device 70 detects a current signal flowing to the plasma side with respect to the signal transmitted to the plasma side, and transmits the current signal to the monitor device 80. The current signal flowing to the plasma side is transmitted from the monitor device 80 to the control device 3, and is received by a communication part 32 of the control device 3. The current value of the received signal is stored in a storage part 31. An analysis part 34 of a control part 33 performs FFT (Fast Fourier Transform) analysis on the current value of the received signal. A calculation part 35 of the control part 33 calculates a plasma electron temperature Tₑ or a plasma electron density Nₑ, which will be described later, on the basis of the analysis result. Thereby, the plasma state can be accurately estimated.

The storage part 31 is realized by the ROM 5 or RAM 6 shown in FIG. 1. The communication part 32 is realized by the communication interface 7. The analysis part 34 and calculation part 35 of the control part 33 are realized by the microprocessor 4.

[Measurement with Probe Device]

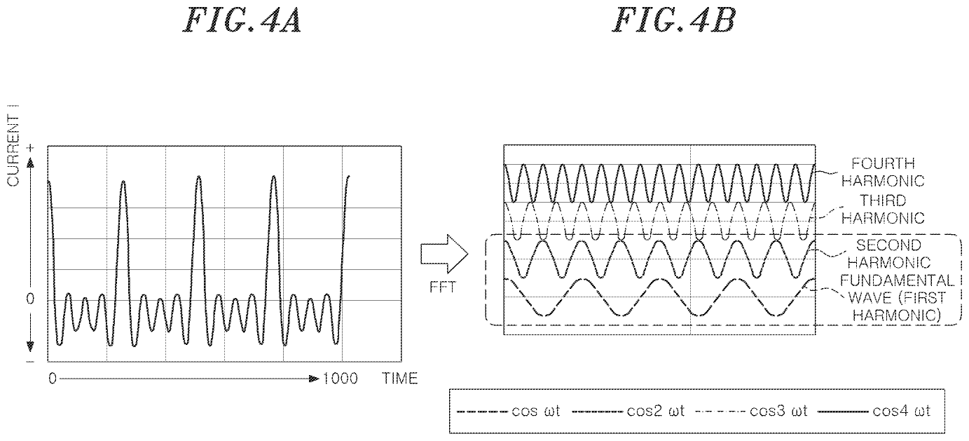

FIGS. 4A and 4B show an example of the current signal that is measured by the probe device 70 of this embodiment as described above and is received by the monitor device 80 and the result of frequency analysis (FFT) of the current signal, respectively. FIG. 4A shows the waveform of the current value I, which is an example of the current signal. The measured current signal (current value I) is transmitted from the monitor device 80 to the control device 3, and is received by the communication part 32 of the control device 3. The current signal is subjected to FFT (Fast Fourier Transform) analysis by the analysis part 34 of the control device 3. Thereby, as shown in FIG. 4B, it is converted into an amplitude component and a phase component for each frequency. In the plasma, current flows exponentially for a given voltage. The measured current value I includes a fundamental wave (first harmonic) component having a fundamental frequency, and a harmonic component whose frequency is twice, three times, and four times that of the fundamental wave.

The amplitude component of the fundamental wave in FIG. 4B indicates the first current of the first harmonic of the frequency of the AC voltage. The harmonic component whose frequency is twice that of the fundamental wave indicates a first current that is twice the frequency of the AC voltage. In calculating the plasma electron density Nₑ and the plasma electron temperature Tₑ below, the first current of the first harmonic and the first current of the second harmonic are used, and the first current of the third harmonic, the fourth harmonic, and higher harmonics, which have little effect on the calculation accuracy of the plasma electron density Nₑ and the plasma electron temperature Tₑ, are not used.

### [Plasma Measurement]

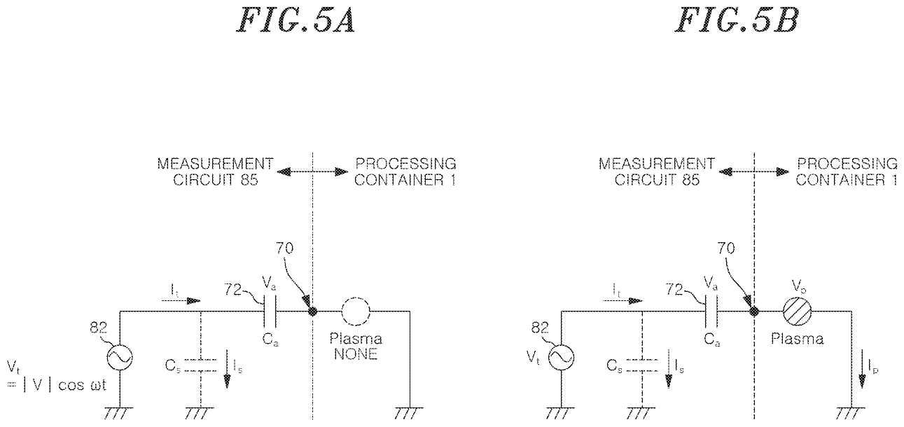

FIGS. 5A and 5B are diagrams showing an example of an equivalent circuit of a measurement system (measurement circuit 85) according to an embodiment. The right side of the dotted line passing through the probe device 70 in FIGS. 5A and 5B indicates the inside of the processing container 1, while the left side of the dotted line is the equivalent circuit of the measurement circuit 85. In the plasma measurement method (preparation stage) according to this embodiment, as shown in FIG. 5A, when no plasma is generated in the processing container 1, the AC voltage (hereinafter referred to as “AC voltage Vₜ”) is applied from the signal transmitter 82 to the probe device 70. At this time, the probe device 70 measures the current It flowing through the measurement circuit 85. Due to the structure of the measurement system, a floating current (hereinafter referred to as “floating current Is”) flows through the stray capacitance Cs of the measurement circuit 85. As shown in FIG. 5A, when no plasma is generated, the current It measured by the measurement circuit 85 is the same as the floating current Is flowing through the stray capacitance Cs. The current It is obtained by measuring a voltage drop through a resistance component (not shown) using a voltmeter (not shown) provided in the measurement circuit 85.

When the AC voltage Vt is applied to the probe device 70 in a state where no plasma is generated, the current It is measured by the measurement circuit 85. The measured current It is an example of the first current including the magnitude (amplitude) and phase of the current, and is the same as the floating current Is in a state where no plasma is generated as shown in FIG. 5A. The current It measured by the measurement circuit 85 is represented by Equation (1).

$${I}_{t} = \frac{1}{4} {en}_{s} {\overline{u}}_{e} A exp ( \frac{{V}_{Bias} - {Φ}_{p}}{{T}_{e}} ) - {en}_{s} {u}_{B} A = \frac{1}{4} {en}_{s} {\overline{u}}_{e} A exp [ \frac{( {V}_{dc} + {V}_{0} cos ω t ) - {Φ}_{p}}{{T}_{e}} ] - {en}_{s} {u}_{B} A \qquad ( 1 )$$

Here, e is the basic amount of electrons, nₛ is the electron density of a plasma sheath surface, ūₑ is the average velocity of electrons, A is an area (i.e., the area of the opening 1b) contacting the plasma of the probe device 70, V_{Bias} is a probe application voltage, ϕₚ is a plasma potential, Tₑ is the electron temperature of plasma, and u_{B} is Bohm velocity. Further, V_{dc} is equal to self-bias voltage, and V₀ is equal to voltage Vp applied to plasma. V₀ is a value obtained by subtracting the voltage Va from the AC voltage Vt applied to the probe device 70, in consideration of the voltage Va at the capacitance component Ca of the capacitor 72.

Equation (1) is transformed using the modified Bessel function of the first kind Ik, and the measured current It is separated into a DC component and an AC component as shown in Equation (2).

$${I}_{t} = \frac{1}{4} {en}_{s} {\overline{u}}_{e} A exp ( \frac{{V}_{dc} - {Φ}_{p}}{{T}_{e}} ) {I}_{0} ( \frac{{V}_{0}}{{T}_{e}} ) - {en}_{s} {u}_{B} A + \frac{1}{2} {en}_{s} {\overline{u}}_{e} A exp ( \frac{{V}_{dc} - {Φ}_{p}}{{T}_{e}} ) {{\sum }^{∞}}_{k = 1} {I}_{k} ( \frac{{V}_{0}}{{T}_{e}} ) cos ( k ω t ) \qquad ( 2 )$$

The upper term on the right side of Equation (2) is the DC component of the measured current It, and the lower term on the right side of Equation (2) is the AC component of the current It, which is cos(kωt) multiplied by a variable. The DC component of the measured current It represents the DC current flowing between the probe device 70 and the plasma. In this embodiment, as shown in FIG. 3, since the probe device 70 and the coaxial cable 81 are not connected in a DC manner by the capacitor 72, the DC component of the current It in Equation (2) is assumed to be zero. As a result, Equation (3) is derived.

$${I}_{t} = \frac{1}{2} {en}_{s} {\overline{u}}_{e} A exp ( \frac{{V}_{dc} - {Φ}_{p}}{{T}_{e}} ) {{\sum }^{∞}}_{k = 1} {I}_{k} ( \frac{{V}_{0}}{{T}_{e}} ) cos ( k ω t ) \qquad ( 3 )$$

When Equation (3) is expanded into a Fourier series, Equation (4) may be obtained.

$$\vert {i}_{1 ω} \vert / \vert {i}_{2 ω} \vert = {I}_{1} ( \frac{{V}_{0}}{{T}_{e}} ) / {I}_{2} ( \frac{{V}_{0}}{{T}_{e}} ) \qquad ( 4 )$$

The left side of Equation (4) is an actual measurement value, which indicates the ratio of the absolute value of the amplitude of the current i1ω of the first harmonic (1ω) to the amplitude of the current i2ω of the second harmonic (2ω). The magnitude of the current i1ω of the first harmonic (1ω) and the magnitude of the current i2ω of the second harmonic (2ω) may be obtained by the analysis part 34 of the control part 33 performing the FFT analysis on the current It (see FIG. 4). |i_{1ω}| is the absolute value of the current value (i_{1ω}) of the first harmonic of the measured current It, and |i_{2ω}| is the absolute value of the current value (i_{2ω}) of the second harmonic of the measured current It. The right side of Equation (4) indicates the ratio of the first harmonic to the second harmonic when the current It is expanded by the modified Bessel function of the first kind. I₁ is a first-order Bessel function, and I₂ is a second-order Bessel function.

Further, the AC component of the current i_{1ω} in the first harmonic is represented by Equation (5).

$${i}_{1 ω} = \frac{1}{2} {en}_{s} {\overline{u}}_{e} A exp ( \frac{{V}_{dc} - {Φ}_{p}}{{T}_{e}} ) {I}_{1} ( \frac{{V}_{0}}{{T}_{e}} ) cos ω t \qquad ( 5 )$$

By substituting the absolute value of the current i_{1ω} in the first harmonic calculated using Equation (5) for |i_{1ω}| of Equation (6), which is an approximate expression of Equation (4), the ion density nᵢ in the plasma is calculated. The ion density nᵢ is equal to the plasma electron density Nₑ. From the above, the plasma electron density Nₑ is calculated.

$${n}_{t} = \frac{\vert {i}_{1 ω} \vert}{2 ( 0.61 {eu}_{B} A )} \frac{{I}_{0} ( {V}_{0} / {T}_{e} )}{{I}_{1} ( {V}_{0} / {T}_{e} )} \qquad ( 6 )$$

Here, e is the basic amount of electrons, u_{B} is Bohm velocity, I₀(V₀/Tₑ) is the zero-order Bessel function, and I₁(V₀/Tₑ) is the first-order Bessel function. Further, A is an area (i.e., the area of the opening 1b) contacting the plasma of the probe device 70, and V₀ is equal to voltage Vp applied to plasma.

Therefore, in order to accurately determine a relationship between the voltage Vp (plasma voltage Vp) applied to the plasma and the current Ip (plasma current Ip) flowing through the plasma, the plasma electron density Nₑ and the plasma electron temperature Tₑ can be precisely measured using Equation (6).

Thus, in the state where plasma is generated in the processing container 1 as shown in FIG. 5(b), the AC voltage Vt is applied from the signal transmitter 82 to the probe device 70. Since the probe device 70 does not use the DC voltage, it may perform measurement even during plasma processing. At this time, the probe device 70 measures the current It flowing through the measurement circuit 85.

As shown in FIG. 5B, due to the structure of the measurement system, the floating current Is flows through the stray capacitance Cs of the measurement circuit 85. In a state where plasma is generated, the plasma current Ip flows. Therefore, the current It measured by the measurement circuit 85 is equal to the sum of the floating current Is flowing through the stray capacitance Cs and the plasma current Ip.

When the AC voltage Vt is applied to the probe device 70 in the state where plasma is generated, the current It is measured by the measurement circuit 85. The measured current It is an example of a second current including the magnitude and phase of the current, and is equal to the sum of the floating current Is and the plasma current Ip.

Therefore, the floating current Is such as the current It (first current) measured in the state where no plasma is generated as shown in FIG. 5A is subtracted from the current It (second current) measured in the state where plasma is generated as shown in FIG. 5B. Thereby, it is possible to calculate the plasma current Ip.

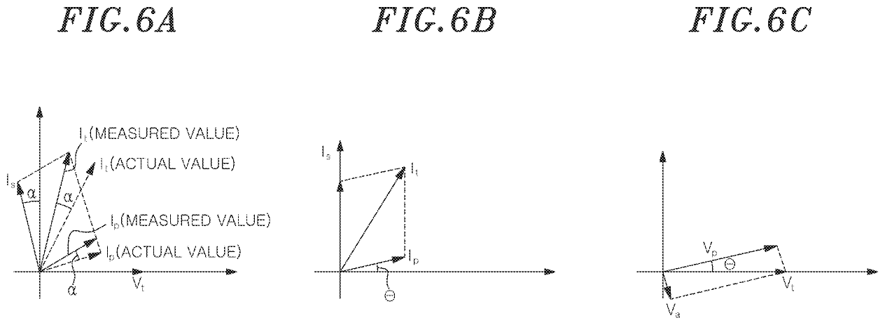

In other words, as shown in FIG. 6B, the plasma current Ip is calculated by subtracting the floating current Is from the current It by vector operation using the magnitude and phase of the current included in the measured current It (second current) and the magnitude and phase of the current included in the floating current Is (first current).

Further, the voltage Va applied to the capacitance component Ca of the capacitor 72 is the plasma current Ip multiplied by 1/jωC (here C=Ca). Therefore, the plasma voltage Vp is calculated by subtracting the voltage Va applied to the capacitance component Ca of the capacitor 72 from the AC voltage Vt applied to the probe device 70 from the signal transmitter 82. This makes it possible to determine the relationship between the voltage Vp applied to the plasma and the plasma current Ip.

Since the voltage Vp applied to the plasma is equal to Vtcosθ as described later (see FIG. 6C), it is possible to derive the plasma voltage Vp without calculating the voltage Va applied to the capacitance component Ca using the value of the capacitance component Ca of the capacitor 72.

### [Phase Shift Due to Measurement System Delay]

In the plasma measurement method according to this embodiment, as shown in FIG. 5A, when plasma is not ignited, the AC voltage Vt is output, the AC voltage Vt is applied to the stray capacitance Cs, and the current value Is flowing through the stray capacitance Cs is measured before the plasma is ignited. In the relationship between voltage and current in the capacitance component C, AC voltage V and AC current I are orthogonal, and the phases of the AC voltage V and AC current I are shifted by 90 degrees. Generally, the phase of the current Is flowing through the stray capacitance Cs advances by 90 degrees with respect to the AC voltage Vt. However, in the measurement circuit 85, a delay time occurs until the monitor device 80 acquires the measured current It due to the temperature and humidity of a substrate forming the measurement circuit 85 or an OP amplifier in the monitor device 80. As a result, the original phase difference between the AC voltage V and the AC current I is 90 degrees, whereas the actual phase difference between the AC voltage Vt and the AC current Is deviates from 90 degrees.

Therefore, when the plasma is not ignited, the AC voltage Vt is applied from the signal transmitter 82 to the probe device 70, and the current It flowing through the substrate (measurement circuit 85) is observed. The measured current It is equal to the floating current Is. Further, the AC voltage Vt and the floating current Is are originally orthogonal to each other. Therefore, the AC voltage Vt and the measured current It should be orthogonal to each other.

On the other hand, when the phase of the measured floating current Is deviates from a value that is 90 degrees ahead of the phase of the AC voltage Vt, it is considered that the measured floating current Is is detected with the phase rotated under the influence of the delay occurring in the measurement circuit 85. Therefore, the phase shift of the current It is calculated in advance as the phase shift of the floating current Is, using the orthogonal relationship between the current It and the AC voltage Vt measured by the measurement circuit 85 when the plasma is not ignited.

For example, in the example of FIG. 6B, the phase of the measured current It is not rotated. In the case that the AC voltage Vt is orthogonal to the current It (=Is) measured when the plasma is not ignited, i.e., in the case that there is no phase shift, the floating current Is is on the Y-axis. In this case, the expression “there is no phase shift” means that the phase of the measured floating current Is is 90 degrees ahead of the phase of the AC voltage Vt. In the example of FIG. 6A, the phase of the measured floating current Is is rotated and detected. When affected by the delay occurring in the measurement circuit 85, as shown in FIG. 6A, the phase of the measured floating current Is deviates from the value that is 90 degrees ahead of the phase of the AC voltage Vt, and shifts by a degrees from the Y-axis. Therefore, the shift value is calculated in advance as the phase shift due to the influence of delay in the measurement system, and the phase shift (phase difference α) is stored in the storage part 31 of the control device 3.

### (Measurement of Plasma Current Ip Considering Phase Shift)

Next, with the plasma ignited, the AC voltage Vt is applied from the signal transmitter 82 to the probe device 70, and the current value It is measured by the measurement circuit 85. When there is no phase shift α, the measured current value It is the sum of the floating current Is and the plasma current Ip as shown in FIG. 6B. By subtracting the floating current Is from the measured current value It using vector operation, the plasma current Ip may be accurately calculated.

On the other hand, when there is a phase difference α in the measured current value It, the floating current Is is subtracted from the measured current value It by vector operation, and the phase difference α measured in advance and shown in FIG. 6A is further subtracted to cancel the delay in the current measurement in the measurement circuit 85 from the phase. Thereby, the plasma current Ip may be accurately calculated.

Here, if plasma is considered as pure resistance, the plasma current Ip and the voltage Vp applied to the plasma have the same phase. Thus, the phase difference between the AC voltage Vt and the voltage Vp applied to the plasma may also be determined from the obtained plasma current Ip. From this phase difference θ (=ωt), the value of the voltage Vp that is actually applied to plasma may be accurately determined using Equation (7).

$$Vp = Vt \times cos θ \qquad ( 7 )$$

As such, the plasma current Ip and the plasma voltage Vp are calculated considering the phase difference α based on the delay occurring in the measurement circuit 85, and the value of the plasma voltage Vp is substituted for V₀ in Equation (6).

Further, the first current having the first harmonic of the frequency of the AC voltage Vₜ is calculated from the measured current It, which is an actual measurement value, by frequency analysis. Then, the absolute value of the first current of the first harmonic is substituted for |i_{1ω}| of Equation (6). This makes it possible to more accurately derive at least any one of the electron density Nₑ, electron temperature Tₑ or ion density Nᵢ of plasma.

In the above description, explanation has been made without distinguishing between the first harmonic current and the second harmonic current, which are necessary for calculating the plasma electron density Nₑ or the like. However, strictly speaking, the phase difference occurring in the measurement circuit 85 is different from the phase difference for the first harmonic current and the phase difference for the second harmonic current. Therefore, in measuring the floating current Is in the state where the plasma is not ignited, the signal transmitter 82 outputs the AC voltage Vt1 of the first harmonic and the AC voltage Vt2 of the second harmonic, respectively. Then, the floating current Is of each of the AC voltage Vt1 of the first harmonic and the AC voltage Vt2 of the second harmonic (the first harmonic floating current Is1 and the second harmonic floating current Is2) is measured. This makes it possible to more accurately calculate the plasma density Nₑ or the like, considering a phase difference α1 with respect to the first harmonic current generated in the measurement circuit 85 and a phase difference α2 with respect to the second harmonic current.

Instead of outputting the first harmonic AC voltage Vt1 and the second harmonic AC voltage Vt2 from the signal generator 82, the AC voltage Vt in which the first harmonic AC voltage Vt1 and the second harmonic AC voltage Vt2 are superimposed may be output. Alternatively, the first harmonic AC voltage Vt1 and the second harmonic AC voltage Vt2 may be separately output at different timings.

The current It (first current) may be repeatedly measured regularly or irregularly in the state where plasma is not generated as shown in FIG. 5A. Then, the phase difference α of the floating current Is may be calculated on the basis of the latest measured current It. In this way, while the plasma is not ignited, the AC voltage Vt for obtaining the current It is continuously applied to the probe device 70. As a result, by continuously updating the phase difference α, which is the latest reference, and storing it in the storage part 31, the plasma state may be more accurately measured on the basis of the current It measured when plasma is being generated.

### [Plasma Measurement Method (Preparation)]

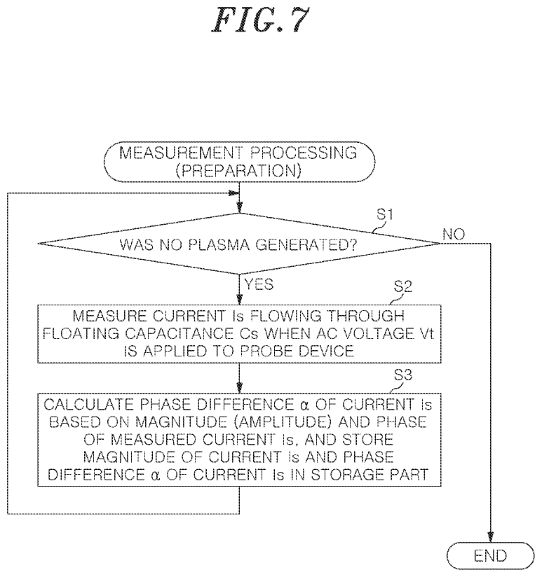

A plasma measurement method (preparation) performed in the state where plasma is not generated as shown in FIG. 5A will be described with reference to FIG. 7. FIG. 7 is a flowchart illustrating an example of the plasma measurement method (preparation) according to an embodiment.

In this process, in step S1, the monitor device 80 determines whether plasma is not generated in the plasma processing apparatus 100. The monitor device 80 may acquire from recipe information whether plasma is generated or not. For example, the monitor device 80 may determine the time during the process from the recipe information, and may determine that plasma is not generated in an idle state before the start and after the end of the process. However, the method for determining whether plasma is generated is not limited thereto. If the monitor device 80 determines that plasma is being generated, it ends this process.

On the other hand, in step S1, when the monitor device 80 determines that plasma is not generated in the plasma processing apparatus 100, the process proceeds to step S2. Then, in step S2, the AC voltage Vt is applied from the signal transmitter 82 to the probe device 70. At this time, the measurement circuit 85 measures the current It (first current) including the magnitude (amplitude) and phase of the current. The measured current It includes the magnitude (amplitude) and phase of the current. The measured current It is equal to the floating current Is (see FIG. 5A). Thus, the floating current Is may be measured by measuring the current It. The signal of the measured floating current Is is transmitted from the monitor device 80 to the control device 3. The control device 3 receives the floating current Is including the magnitude (amplitude) and phase of the current.

Next, in step S3, the calculation part 35 of the control device 3 calculates the phase shift (phase difference α) of the floating current Is on the basis of the floating current Is including the magnitude (amplitude) and phase of the current. In the relationship between voltage and current in the capacitance component C, the phases of the AC voltage V and the AC current I are shifted by 90 degrees. Thus, from the orthogonal relationship between the AC voltage Vt and the current It measured by the measurement circuit 85, the calculation part 35 calculates the phase shift of the first current (current It), that is, the phase difference α in which the phase of the floating current Is is further shifted from a normal state in which the phase is shifted by 90 degrees from the phase of the AC voltage Vt. Then, the calculation part 35 stores the measured magnitude of the floating current Is and the calculated phase difference α in the storage part 31, and ends this process.

### [Measurement Process]

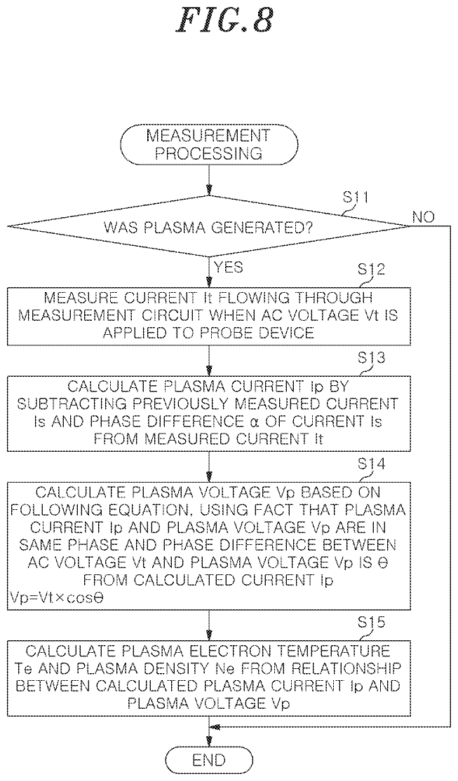

A measurement process performed in a state where plasma is generated, an example of which is shown in FIG. 5B, will be described with reference to FIG. 8. FIG. 8 is a flowchart illustrating an example of the plasma measurement method according to an embodiment. Before the plasma measurement method of FIG. 8 is executed, it is assumed that the plasma measurement method of FIG. 7 is executed at least once, and the magnitude of the floating current Is and the phase difference α are stored in the storage part 31 of the control device 3.

In this process, in step S11, the monitor device 80 determines whether plasma is being generated in the plasma processing apparatus 100. The determination method may be the method described in step S1 of FIG. 7. If the monitor device 80 determines that plasma is not generated, it ends this process.

On the other hand, in step S11, if the monitor device 80 determines that plasma is generated in the plasma processing apparatus 100, the process proceeds to step S12. Then, in step S12, the AC voltage Vt is applied from the signal transmitter 82 to the probe device 70. At this time, the measurement circuit 85 measures the current It (second current) including the magnitude (amplitude) and phase of the current. Next, in step S13, vector operation is performed to subtract the magnitude of the floating current Is measured in advance and the phase difference α of the floating current Is from the measured current It (see FIGS. 5B, 6A and 6B). Thereby, the plasma current Ip may be accurately calculated by canceling the delay in current measurement in the measurement circuit 85 from the phase of the measured current It.

Next, in step S14, the voltage Vp applied to the plasma is calculated. If the plasma is considered as pure resistance, the plasma current Ip and the voltage Vp applied to the plasma have the same phase. Thus, the phase difference between the AC voltage Vt and the voltage Vp applied to the plasma may be determined from the obtained plasma current Ip. From this phase difference θ(=ωt), the value of the voltage Vp that is actually applied to plasma may be accurately determined using Equation (7).

Next, in step S15, the plasma electron temperature Tₑ and the plasma electron density Nₑ are calculated using Equation (6) from the calculated relationship between the plasma current Ip and the plasma voltage Vp, and this process ends.

As described above, according to the plasma measurement method and plasma processing apparatus of this embodiment, the plasma state can be more precisely measured by taking into account the delay caused by the measurement circuit 85.

The embodiments disclosed herein should be considered to be illustrative in all respects and not restrictive. The embodiments may be changed or modified in various forms without departing from the scope and spirit of the appended claims. The matters described in the plurality of embodiments may be configured in other ways without being inconsistent, and may be combined within a range that is not contradictory.

The plasma processing apparatus of the present disclosure is applicable to any type of apparatus including an Atomic Layer Deposition (ALD) apparatus, Capacitively Coupled Plasma (CCP), Inductively Coupled Plasma (ICP), Radial Line Slot Antenna (RLSA), Electron Cyclotron Resonance Plasma (ECR), and Helicon Wave Plasma (HWP).

The plasma processing apparatus disclosed in this specification can be applied to any of a single-wafer apparatus that processes substrates one by one, a batch apparatus that processes a plurality of substrates at once, and a semi-batch apparatus.

1. A plasma measurement method for measuring a plasma state using a probe device that is provided in a plasma processing apparatus, and a measurement circuit including a signal transmitter that outputs an AC voltage, the method comprising:
step (A) of measuring a first current including a magnitude and phase of current in the measurement circuit when the AC voltage is output from the signal transmitter to the probe device, in a state where no plasma is generated in the plasma processing apparatus;
step (B) of measuring a second current including a magnitude and phase of current in the measurement circuit when the AC voltage is output from the signal transmitter to the probe device, in a state where plasma is generated in the plasma processing apparatus; and
step (C) of measuring current flowing through the plasma by vector operation using the magnitude and phase of the current included in the measured first current and second current.

2. The plasma measurement method of claim 1, wherein step (A) calculates a phase shift occurring in the measurement circuit on the basis of the phase of the measured first current, and
step (C) measures the current flowing through the plasma by subtracting the magnitude of the first current and the phase shift from the magnitude of the second current.

3. The plasma measurement method of claim 2, wherein step (C) calculates the phase shift, on the basis of an orthogonal relationship between the AC voltage and the first current measured by the measurement circuit.

4. The plasma measurement method of claim 1, further comprising:
step (D) of deriving at least any one of electron density, electron temperature, or ion density of the plasma indicating the plasma state, on the basis of the measured current flowing through the plasma.

5. The plasma measurement method of claim 4, wherein, in step (D), a first current of a first harmonic of frequency of the AC voltage and a first current of a second harmonic of frequency of the AC voltage are calculated by frequency analysis from the measured current flowing through the plasma, and
at least any one of the electron density, the electron temperature, or the ion density of the plasma is derived using the calculated first current of the first harmonic and the calculated first current of the second harmonic.

6. The plasma measurement method of claim 1, wherein, in step (A), the first current is repeatedly measured regularly or irregularly in a state where no plasma is generated.

7. The plasma measurement method of claim 2, wherein, in step (A), the first current is repeatedly measured regularly or irregularly in a state where no plasma is generated.

8. The plasma measurement method of claim 3, wherein, in step (A), the first current is repeatedly measured regularly or irregularly in a state where no plasma is generated.

9. The plasma measurement method of claim 4, wherein, in step (A), the first current is repeatedly measured regularly or irregularly in a state where no plasma is generated.

10. The plasma measurement method of claim 5, wherein, in step (A), the first current is repeatedly measured regularly or irregularly in a state where no plasma is generated.

11. The plasma measurement method of claim 2, wherein, in step (A), the phase shift is calculated on the basis of the latest measured phase of the first current.

12. The plasma measurement method of claim 1, wherein the probe device is installed in an opening formed in a wall of a processing container of the plasma processing apparatus via a sealing member that seals between a vacuum space and an atmospheric space.

13. The plasma measurement method of claim 2, wherein the probe device is installed in an opening formed in a wall of a processing container of the plasma processing apparatus via a sealing member that seals between a vacuum space and an atmospheric space.

14. The plasma measurement method of claim 3, wherein the probe device is installed in an opening formed in a wall of a processing container of the plasma processing apparatus via a sealing member that seals between a vacuum space and an atmospheric space.

15. The plasma measurement method of claim 4, wherein the probe device is installed in an opening formed in a wall of a processing container of the plasma processing apparatus via a sealing member that seals between a vacuum space and an atmospheric space.

16. The plasma measurement method of claim 5, wherein the probe device is installed in an opening formed in a wall of a processing container of the plasma processing apparatus via a sealing member that seals between a vacuum space and an atmospheric space.

17. A plasma processing apparatus comprising a probe device, a measurement circuit including a signal transmitter that outputs an AC voltage, and a control device having a communication part and a control part,
wherein the communication part receives a first current including a magnitude and phase of current measured in the measurement circuit when the AC voltage is output from the signal transmitter to the probe device, in a state where no plasma is generated in the plasma processing apparatus, and receives a second current including a magnitude and phase of current measured in the measurement circuit when the AC voltage is output from the signal transmitter to the probe device, in a state where plasma is generated in the plasma processing apparatus, and
wherein the control part measures current flowing through the plasma by vector operation using the magnitude and phase of the current included in the received first current and second current, and measures the plasma state on the basis of the measured current flowing through the plasma.
